(19) United States
(12) Patent Application Publication
(10) Pub. No.: US 2014/0220875 A1
(43) Pub. Date: Aug. 7, 2014

(54) FLOOR PAN FOR CONNECTING A ROOF-MOUNTED COOLING DEVICE TO THE ROOF OF A SWITCHGEAR CABINET

(71) Applicant: Manfred Immel, Mittenaar 1 (DE)

(72) Inventor: Manfred Immel, Mittenaar 1 (DE)

(73) Assignee: RITTAL GMBH & CO. KG, HERBORN (DE)

(21) Appl. No.: 13/261,808

(22) PCT Filed: Jun. 20, 2012
(86) PCT No.: PCT/DE2012/000639

§ 371 Date: Mar. 31, 2014

(30) Foreign Application Priority Data
Aug. 16, 2011 (DE) 20 2011 050 995.8

(51) Int. Cl. H05K 7/20

(52) U.S. Cl. CPC H05K 7/20009
USPC 454/237

(57) ABSTRACT

A floor pan for connecting a roof-mounted cooling device to the roof of a switchgear cabinet for coupling an interior of the switchgear cabinet to the inner circuit of the refrigerant circulation of the roof-mounted cooling device, having at least one air inlet opening aligned with the hot air outlet of the inner chamber of the switchgear cabinet and at least one air outlet opening communicating with the cold air inlet(s) of the inner chamber of the switchgear cabinet. A plurality of air outlet openings are arranged surrounding at least one air inlet opening, and at least some air outlet openings are covered by ventilation louvres that are pivotable about an axis running in the plane of the floor and are rotatable about an axis running perpendicular to the plane of the floor.

The invention relates to a floor pan for connecting a roof-mounted cooling device to the roof of a switchgear cabinet for coupling an inner chamber of the switchgear cabinet to the inner circuit of the refrigerant circulation of the roof-mounted cooling device, having at least one air inlet opening aligned with the hot air outlet if the inner chamber of the switchgear cabinet and at least one air outlet opening communicating with the cold air inlet(s) of the inner chamber oft the switchgear cabinet, wherein the air inlet opening(s) and the air outlet opening(s) are provided in the base of the floor pan and are covered by ventilation grilles or ventilation louvres.

A floor pan of this type is known from DE 102 05 646 A1. That floor pan has proven to provide a simple variable air conveyance between the switchgear cabinet and the cooling device and, moreover, simultaneously to achieve and to simplify decoupling of the inner circuit and the outer circuit of the refrigerant circulation by having a simple constructional design. The floor pan may easily be adapted to the air conveyance between the interior of the switchgear cabinet and the roof-mounted cooling device and simultaneously forms the receptacle for the components of die inner circuit when the completed cooling device is coupled to the floor pan and closes the same. The inner circuit with its components is relocated into the floor pan, coupled to the interior of the switchgear cabinet and decoupled from the outer circuit of the refrigerant circulation.

However it may be the situation, that the thermal conditions in the interior of the switchgear cabinet change or that an already existing switchgear cabinet must be air conditioned better than before.

Accordingly, it is the object of the invention to improve the known floor pan in that cold air flows may be adapted to the actual temperature conditions within the switchgear cabinet even at a later date.

This object is solved by a floor pan according to claim 1. Advantageous and embodiments a subject matter of the subclaims.

According to the invention it is provided that a plurality of air outlet openings are arranged surrounding the at least one inlet opening and that at least some of the outlet openings are covered by ventilation louvres, that are pilotable about an axis running in the plane of the base and are rotatable about an axis running perpendicular to the plane of the base. Having this arrangement, a space optimized conveyance of the cold air flows is possible. By rotating the ventilation louvres, the orientation of the cold air flow may be chosen as desired, by pivoting, the cold air volume may be adjusted.

In a preferred embodiment, for a floor pan having a substantial rectangular base, it is provided that a centered air inlet opening is surrounded by four air outlet openings which are respectively arranged in a corner region in of the base.

Preferably, the ventilation louvres of any air outlet opening can be pivoted and/or rotated manually or driven by a motor independently from those of other air outlet openings. For example, a large cold air volume can actively be conveyed to thermally highly stressed areas, while other areas receive only a little flow or no flow at all.

It is particular preferred that ventilation louvres are disposed within an insert or a top part of the air ventilation openings, so that they can simply be plugged for example onto existing connecting pieces. Retrofitting or exchange is possible in a most simple manner.

According to an embodiment, the ventilation louvres for respectively one air outlet opening are coupled via a lever assembly.

It may be provided that the ventilation louvres for respectively one air outlet opening are pivot able between a first position where the air outlet opening is completely closed, and a second position, where the air outlet opening is opened to the maximum. Any intermediate position may be taken and maintained.

Finally, is may be also be provided, that the ventilation louvres for respectively one air outlet opening are continuously rotatable or can be rotated in steps.

The invention will be explained in detail below, merely by example with the aid of the appended drawings. The representations will illustrate the basic principles of the invention and are not necessarily to scale. It is shown in:

FIG. 1 an embodiment of a top part for an air outlet opening of a floor pan according to the present invention in a perspective view seen from the cooling device side;

FIG. 2 a sectional view of a top part of FIG. 1 having the ventilation louvres in an open position;

FIG. 3 a sectional view similar to FIG. 2, however having the ventilation louvres in the closed position;

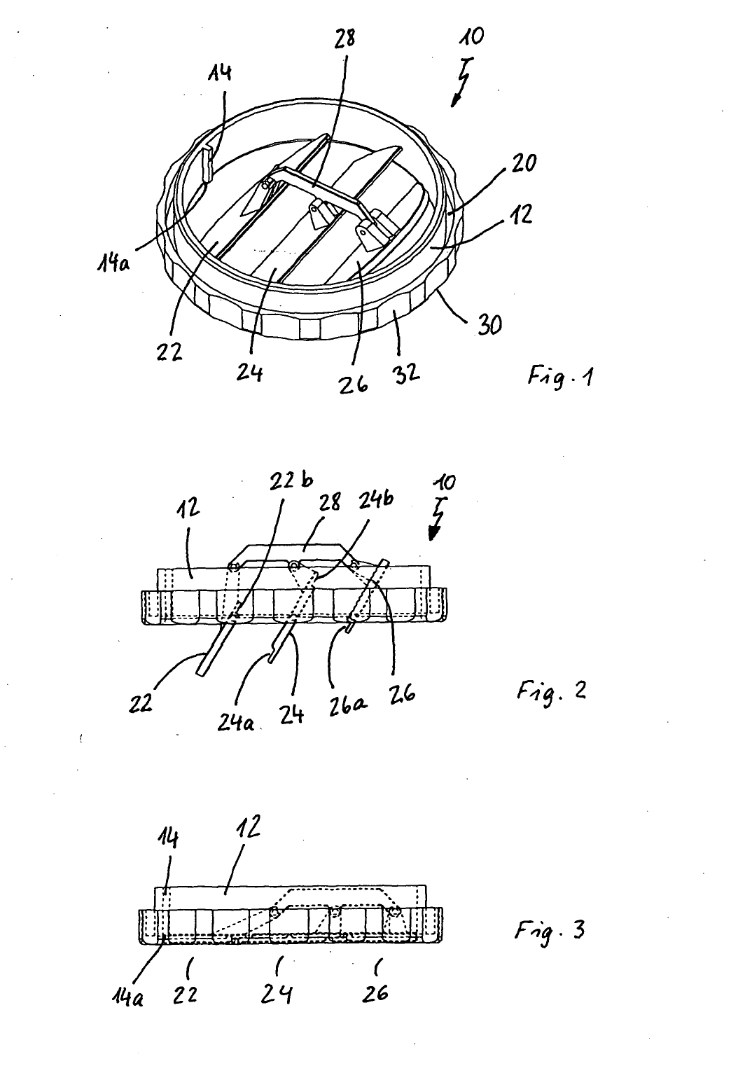

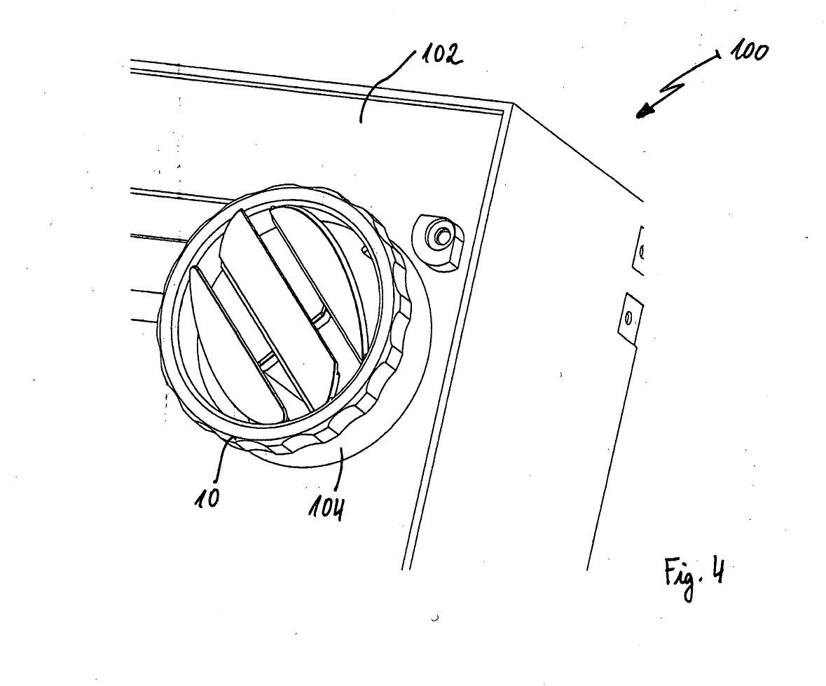

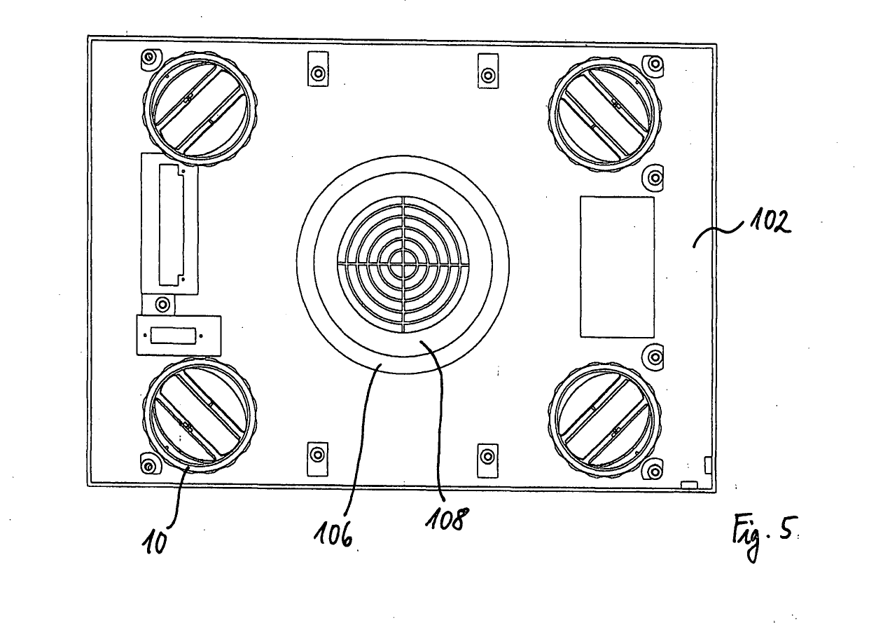

FIG. 4 a view of a top part for an air inlet opening in a built-in waste seen from the side of the interior of the switchgear cabinet; and

FIG. 5 a top view of the base of a floor pan according to an embodiment of the present invention, seen from the side of the interior of the switchgear cabinet.

According to a preferred embodiment of the present invention, a floor pan for connecting a roof-mounted cooling device to the roof of a switchgear cabinet for coupling an interior of the switchgear cabinet to the inner circuit of the refrigerant circulation of the roof-mounted cooling device is provided with top parts 10 for air outlet openings, as shown in various illustrations in FIGS. 1 to 3. Top parts 10 are plugged onto existing connection pieces and maybe easily be exchanged or retrofitted.

FIG. 1 shows a perspective view of a top part 10 essentially seen in a built in state from the side of the roof-mounted cooling device. Three ventilation louvres 22, 24, 26 are disposed in a hollow-cylindrical body 12, the outer radius thereof corresponding substantially to the inner radius of a connecting piece to be equipped with top part 10 where the ventilation louvres are hinged to a lever 28, so that they may be commonly pivoted about an axis, which in the built in-waste lie within the plane of the base of the floor pan or parallel thereto. In the inner surface of the hollow-cylindrical body 12, a rib 13 extending in axial direction is provided which limits the pivot movement of ventilation louvres 22, 24, 26. To this end, a lower abutment face 14a is formed on rib 14 where in the closed position one of the ventilation louvres, namely ventilation louvre 22, abuts. Hollow-cylindrical body 12 is coaxially surrounded by a ring body 30 and connected there to in a rotatable fixed manner, so that a continuous groove 20 is formed between hollowed-cylindrical body 12 and ring body 30, where the width thereof approximately corresponds to the wall thickness of the connecting piece onto which top part 10 is to be plugged. To summarize, the dimensions of hollow-cylindrical body 12 and ring body 30 are tuned in radial and axial direction, such that top part 10 is held in a force-fitting manner on the connecting piece, and no tool or additional fixing elements for assembly are needed.

Ring body 30 is provided with a plurality of troughs 32 at its outer surface which serve as a grip assistance for plugging top part 10 and for rotating top part 10 as needed. The angular position of ventilation louvres 22, 24, 26 may easily be varied from the interior of a switchgear cabinet by pressing on the rim region of one or several ventilation louvres 22, 24, 26.

While rotating or pivoting the louvres is done manually in the illustrated embodiment, a motor drive or another drive may be equally provided which produces these movements, optionally controlled, for example depending on prevailing temperatures and/or pressures.

Moreover, top part 10 as previously described is designed for continuous rotation. It may also be provide to design top part 10 such that a rotational movement may be performed in steps.

FIG. 2 shows a sectional view of top part 10 of FIG. 1, where ventilation louvres 22, 24, 26 are in an open position. Louvre 22 comprises at a free end thereof which hinged to lever 28, a step 22b, which in its dimensions corresponds approximately to a step 24a which is provided at a free end of louvre 24. Louvre 24 further comprises a step 24b at an end hinged to lever 28 which is approximately complimentary to a step 26a at a free end of louvre 26. By manually moving louvre 22 at its free end, also louvres 24, 26 are correspondingly moved by transferring the movement via lever 28, so that the free open surface of hollow-cylindrical body 12 may be maximized or refused as needed, and that into a closed position, which is shown in the sectional view of FIG. 3. In the closed position, the free end of ventilation louvre 22 lies on abutment surface 14 of rib 14, steps 22b and 24a as well as steps 24b and 26a of the relevant louvres adjoin each other, so that hollow-cylindrical body 12 is closed, and no air can pass.

FIG. 4 shows a view of a top part 10 for an air inlet opening in a base 102 of a floor pan 100, top part 10 being plugged onto a connecting piece 104 surrounding the air inlet opening. Top part 10 may now be rotated on connecting piece 104 until a desired flow direction of the cold air is achieved in an open position. Since top part 10 may still be rotated at a later date quick adjustment to varying temperature conditions within the switchgear cabinet is possible.

FIG. 5 shows a preferred embodiment wherein in the rectangular base 102 of a floor pan an air inlet opening 106 for hot air is centrally arranged, which opening is covered by ventilation grill 108. In the corner regions of base 102, a respective air outlet opening is provided which is equipped with a top part 10 as descript in connection with FIG. 4. All top parts 10 can be rotated independently from another, the ventilations louvres thereof may be pivoted as desired, so that in the interior of the switchgear cabinet adjusted and optimized air flows, in particular cold air flows, may be produced which can still be changed at a later date.

The features of the invention disclosed in the previous description, in the drawings and in the claims, may both individually and in any combination, be material for realizing the invention.

1-7. (canceled)

8. A floor pan for connecting a roof-mounted cooling device to the roof of a switchgear cabinet for coupling an interior of the switchgear cabinet to the inner circuit of the refrigerant circulation of the roof-mounted cooling device, having
at least one air inlet opening aligned with the hot air outlet of the inner chamber of the switchgear cabinet and
at least one air outlet opening communicating with the cold air inlet(s) of the inner chamber of the switchgear cabinet,
wherein the air inlet opening(s) and the air outlet opening(s) are provided in the base of the floor pan and are covered by ventilation grilles or ventilation louvres, and a plurality of air outlet openings are arranged surrounding the at least one air inlet opening and at least some of the air outlet openings are covered by ventilation louvres that are pivotable about an axis running in the plane of the base and are rotatable about an axis running perpendicular to the plane of the base.

9. The floor pan of claim 8, having a substantially rectangular floor, wherein a centered air inlet opening is surrounded by four air outlet openings which are respectively arranged in a corner region of the base.

10. The floor pan of claim 8, wherein the ventilation louvres of any air outlet opening can be pivoted and/or rotated manually or driven by a motor independently from those of other air outlet openings.

11. The floor pan of claim 8, wherein the ventilation louvres are disposed within an insert or a top part for the air ventilation openings.

12. The floor pan of claim 8, wherein the ventilation louvres for respectively one air outlet opening are coupled via a lever assembly.

13. The floor pan of claim 8, wherein the ventilation louvres for respectively one air outlet opening are pivotable between a first position where the air outlet opening is completely closed, and a second position, where the air outlet opening is opened to the maximum.

14. The floor pan of claim 8, wherein the ventilation louvres for respectively one air outlet opening are continuously rotatable or can be rotated in steps.
